(19) United States
(12) Patent Application Publication
(10) Pub. No.: US 2008/0173943 A1
(43) Pub. Date: Jul. 24, 2008

(54) Method of forming high voltage semiconductor device and the high voltage semiconductor device using the same

(75) Inventor: Mi-Hyun Kang, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/009,244

(22) Filed: Jan. 17, 2008

(30) Foreign Application Priority Data
Jan. 22, 2007 (KR) 10-2007-0006642

(51) Int. Cl. H01L 29/786; H01L 21/336

(52) U.S. Cl. 257/347; 438/151; 257/E29.273; 257/E21.411

(57) ABSTRACT

A method of forming a high voltage semiconductor device includes forming a thermal oxide layer on a semiconductor substrate where a trench is formed, forming a chemical vapor deposition (CVD) oxide layer on the thermal oxide layer, and etching the CVD oxide layer and the thermal oxide layer at different etching selectivities to form a gate insulating layer having an inclined sidewall and a device isolation pattern. Thus, a gate insulating layer having a sufficiently large thickness and a device isolation pattern can be formed simultaneously by means of simple process steps and degradation of the device can be suppressed even when a high voltage is applied.

### CROSS-REFERENCE TO RELATED APPLICATIONS

This U.S. non-provisional patent application claims priority under 35 U.S.C. §119 to Korean Patent Application No. 10-2007-0006642, filed on Jan. 22, 2007, the entire contents of which are herein incorporated by reference in their entirety.

### FIELD OF THE INVENTION

The present invention relates to methods of forming semiconductor devices and the semiconductor devices using the same, and more particularly, to a method of forming a high voltage semiconductor device and the high voltage semiconductor device formed thereby.

### BACKGROUND OF THE INVENTION

Large scale integrated circuits (LSIs) are used to drive flat panel displays, vehicles, office automation (OA) and peripheral devices, and motors. An LSI circuits includes a high voltage device and a low voltage device, which can be merged into one chip. The high voltage semiconductor device has a breakdown voltage of several tens volts or at least 100 volts.

Generally, high voltage semiconductor devices are formed on a silicon-on-insulator (SOI) substrate. The SOI substrate can be formed by stacking a buried insulating layer and a single crystalline silicon layer on a silicon substrate. A region including the high voltage semiconductor devices can be separated from a region including the low voltage semiconductor devices by deep trench isolation.

Dopants having different electrical characteristics are implanted into the region including the high voltage semiconductor devices to define impurity regions such as a drift region and a P-well region. The impurity regions have a concentration distribution, where a specific profile is exhibited from the surface of the substrate to operate the high voltage semiconductor devices. The trench can have a depth sufficient enough to isolate the impurity regions of the high voltage semiconductor devices and the low voltage semiconductor devices. For instance, at the SOI substrate, the depth of the trench can be equal to a thickness of the single crystalline silicon.

Breakdown voltage is one evaluative characteristics of a high voltage device. The breakdown voltage must be controlled properly so that breakdown does not occur within a given voltage range. The breakdown voltage can be optimized by controlling a length of a field plate, or a length and/or a depth of a drift region in a horizontal high voltage semiconductor device.

A value of a vertical breakdown voltage can be determined by a depth and an impurity concentration of a P-drift region. A value of a horizontal breakdown voltage can be determined by a distance between a source and a drain. There is a close correlation between the impurity concentration of the drift region and an ON-resistance of a power device. For instance, when the impurity concentration of the drift region is low, breakdown occurs at the edge of the drain. In the meantime, when the impurity concentration of the drift region is high, breakdown occurs at an edge of a gate.

A high voltage semiconductor device and a low voltage semiconductor device are different in their structures and forming methods. For example, a gate insulating layer of the high voltage semiconductor device can be formed to be thicker than that of the low voltage semiconductor device. A high voltage applied to a gate electrode of the high voltage semiconductor device is liable to damage a thin gate insulating layer. Thus, the gate insulating layer of the high voltage semiconductor device is formed with a larger thickness than that of the low voltage semiconductor device to be durable against a high voltage.

The gate insulating layer can be formed by means of a conventional thermal oxidation process. Therefore, if the substrate is annealed to form a thick gate insulating layer of the high voltage semiconductor device, a concentration profile of the impurities previously implanted at a high temperature for the long period of time can be changed. In other words, due to the thermal oxidation process, impurities diffuse from the surface to the bottom of the substrate to redistribute the impurity region. Consequently, the concentration profile of the impurities can be changed. Since a breakdown voltage of the high voltage semiconductor device changes according to the concentration profile of the impurities, characteristics of the semiconductor device are not shown as estimated in the design step. That is, reliability and process yield of the semiconductor device can be degraded. Since the gate insulating layer of the high voltage semiconductor device is formed to be thick, an electric field is concentrated on the corner of the gate insulating layer to deteriorate a device.

### SUMMARY OF THE INVENTION

In accordance with one aspect of the present invention, there is provided a method of forming a high voltage semiconductor device including: thermally oxidizing a semiconductor device to form a thermal oxide layer; uniformly forming a chemical vapor deposition (CVD) oxide layer on the thermal oxide layer; forming a gate mask pattern on the CVD oxide layer; etching the CVD oxide layer and the thermal oxide layer using the gate mask pattern at different etch rates to expose a portion of the semiconductor substrate, thereby forming a gate insulating layer having an inclined sidewall; and forming a gate electrode on the gate insulating layer.

The semiconductor substrate can be a silicon-on-insulator (SOI) substrate including a buried insulating layer and a semiconductor layer.

Forming the CVD oxide layer can further comprise forming a trench by etching a portion of the thermal oxide layer and the semiconductor layer.

Forming the trench can comprise: forming a mask insulating layer on the thermal oxide layer; forming a photoresist pattern on the mask insulating layer; etching the mask insulating layer and the thermal oxide layer using the photoresist pattern to form a trench mask pattern; and etching the semiconductor layer using the trench mask pattern to expose the buried insulating layer.

The method can include forming the CVD oxide layer on a bottom surface and a sidewall of the trench, and on the thermal oxide layer.

The method can further comprise filling the trench, in which the CVD oxide layer is formed, with an insulating material.

The insulating material can be polysilicon.

Forming the trench can comprise forming a polysilicon layer on the semiconductor substrate to fill the trench and planarizing the polysilicon layer down to a top surface of the CVD oxide layer to form a polysilicon pattern.

The gate mask pattern can cover the polysilicon pattern, and forming the gate insulating layer can be simultaneously performed with forming a device isolation pattern including the polysilicon pattern.

The gate electrode can be formed on a top surface of the gate insulating layer and the semiconductor substrate.

The method can further comprise forming a capping oxide layer to cover a top surface of the polysilicon pattern.

The method can include defining an impurity region at the semiconductor substrate.

In accordance with another aspect of the present invention, provided is a high voltage semiconductor device which includes: a semiconductor substrate including a buried insulating layer and a semiconductor layer; a gate insulating layer having a bottom surface that is even with a flat top surface of the semiconductor substrate and including a thermal oxide layer pattern and a CVD oxide layer pattern that are stacked sequentially, wherein a sidewall of the gate insulating layer is inclined; and a gate electrode formed on the gate insulating layer.

The high voltage semiconductor device can further comprise a device isolation pattern spaced apart from the gate insulating layer and penetrating the semiconductor layer from the surface of the semiconductor substrate to expose the buried insulating layer, the device isolation pattern including a CVD oxide layer pattern and a polysilicon pattern.

The device isolation pattern can include a protrusive portion protruding above the top surface of the semiconductor substrate, and a sidewall of the protrusive portion is inclined.

A section of the gate insulating layer can be formed in an isosceles trapezoid shape.

The gate electrode can have a step difference along a profile of a top surface of the gate insulating layer and the semiconductor substrate.

The high voltage semiconductor device can further comprise a capping oxide layer formed on a top surface of the device isolation pattern.

### BRIEF DESCRIPTION OF THE FIGURES

FIGS. 1A to 1H are cross-sectional views illustrating an embodiment of a method of forming a high voltage semiconductor device and the high voltage semiconductor device in accordance with aspects of the present invention.

FIGS. 2A and 2B are cross-sectional views illustrating another embodiment of a method of forming a high voltage semiconductor device in accordance with aspects of the present invention.

### DETAILED DESCRIPTION OF PREFERRED EMBODIMENTS

Embodiments of the present invention will now be described more fully with reference to the accompanying drawings. This invention can, however, be embodied in many different forms and should not be construed as being limited to the embodiments set forth herein.

It will be understood that, although the terms first, second, etc. are be used herein to describe various elements, these elements should not be limited by these terms. These terms are used to distinguish one element from another, but not to imply a required sequence of elements. For example, a first element can be termed a second element, and, similarly, a second element can be termed a first element, without departing from the scope of the present invention. As used herein, the term “and/or” includes any and all combinations of one or more of the associated listed items.

In the drawings, the thickness of layers and regions are exaggerated for clarity. It will also be understood that when an element, such as a layer, region or substrate, is referred to as being “on” or “onto” or “connected to” or “coupled to” another element, it can lie directly on or be connected or coupled to the other element or intervening elements or layers can also be present, unless one element is referred to as being “directly on,” “directly coupled to” or “directly connected to” another element. Like reference numerals refer to like elements throughout the specification.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements, and/or components, but do not preclude the presence or addition of one or more other features, steps, operations, elements, components, and/or groups thereof.

Spatially relative terms, such as “beneath,” “below,” “lower,” “above,” “upper” and the like may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (e.g., rotated 90 degrees or at other orientations) and the spatially relative descriptors used herein interpreted accordingly.

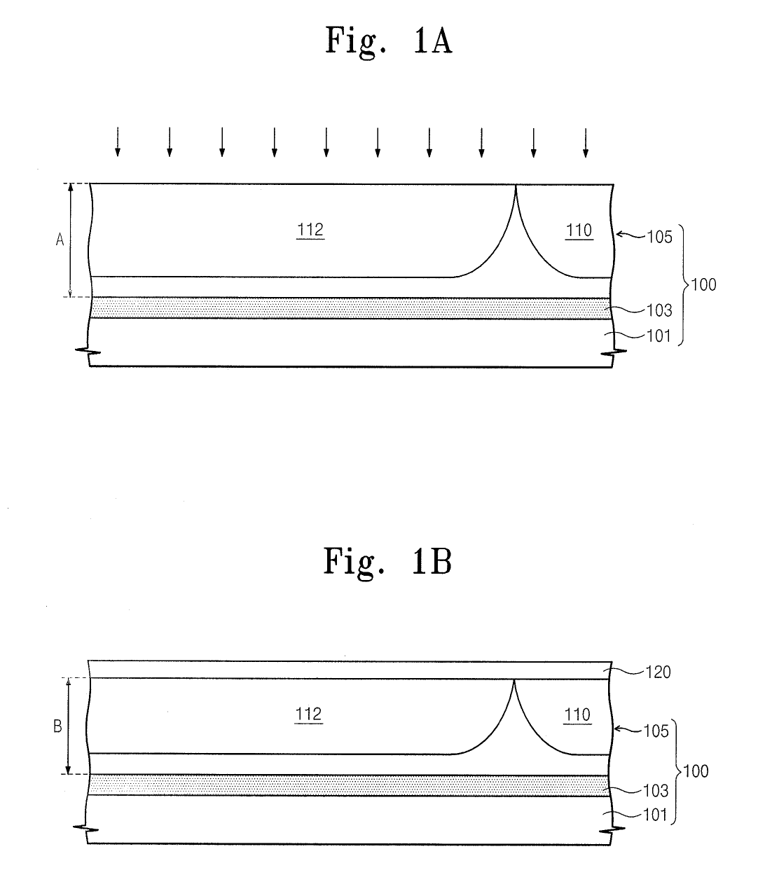

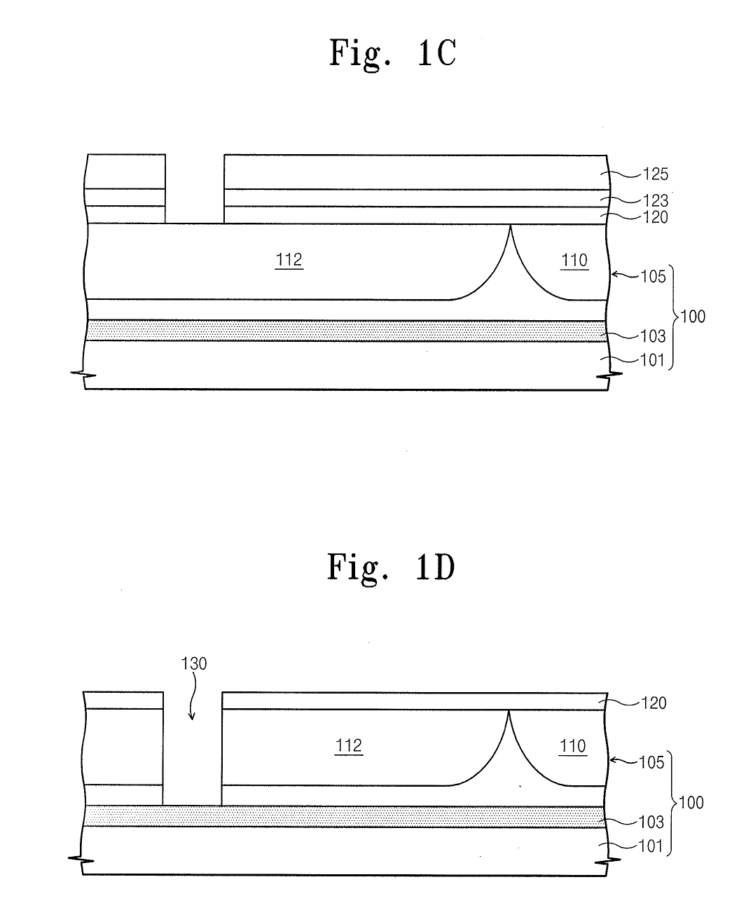

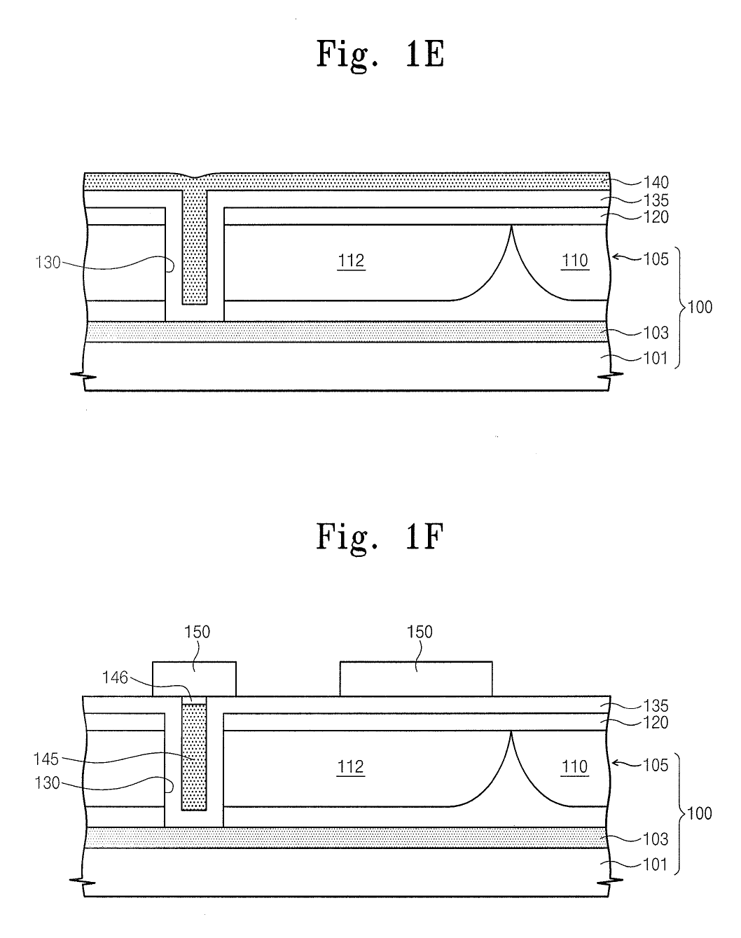

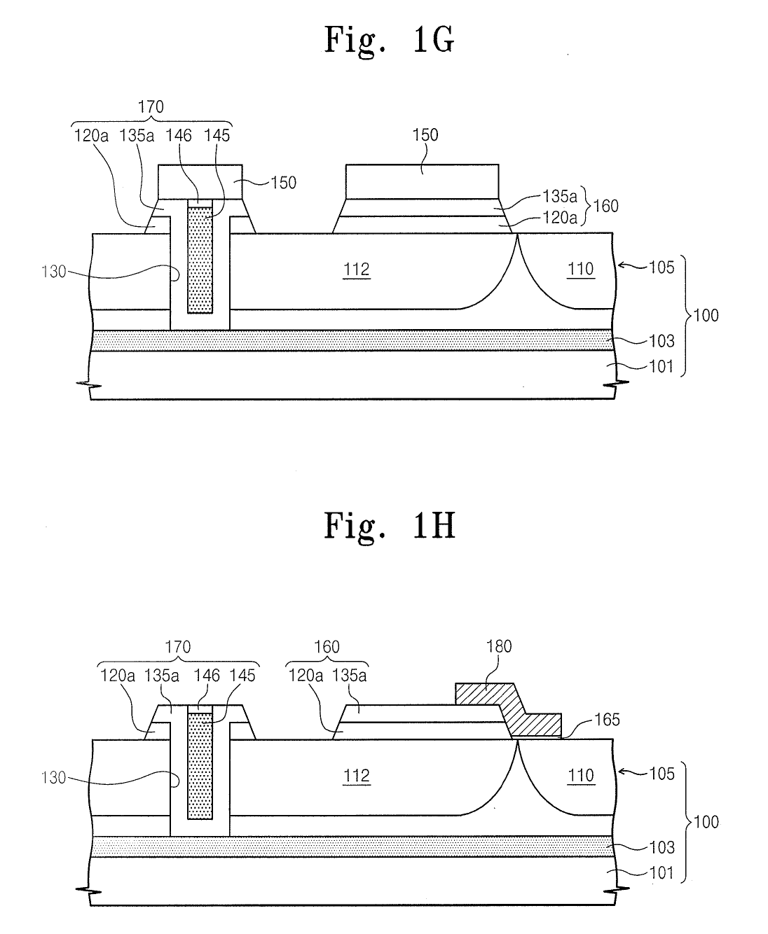

FIGS. 1A to 1H illustrate an embodiment of a method of forming a high voltage semiconductor device in accordance with aspects of the present invention.

Referring to FIG. 1A, a semiconductor substrate 100 is provided. The semiconductor substrate 100 can be a silicon on insulator SOI substrate. The semiconductor substrate 100 can include a lower silicon substrate 101, a buried insulating layer 103 on the lower silicon substrate 101, and a single crystalline silicon layer 105 having a first thickness “A” on the buried insulating layer 103.

Impurities are implanted into the semiconductor substrate 100 using a mask pattern (not shown) to define impurity regions. An implantation of the impurities can be performed using an ion implantation process (IIP).

For instance, the implantation of the impurities can include a plurality of steps of sequentially implanting different impurities. Due to the implantation of the impurities, a p-type drift region 110 can be formed at the single crystalline silicon layer 105 to have a predetermined depth from the semiconductor substrate, and an n-type well region 112 can be formed at the boundary with the p-type drift region 110.

The p-type drift region 110 and the n-type well region 112 can have impurity concentration profiles having different forms relative to the surface of the semiconductor substrate. A breakdown voltage can be controlled by the p-type drift region 110 and the n-type well region 112, i.e., the breakdown voltage can be determined by the impurity concentration and depth. Further, an impurity concentration of the p-type drift region 110 has a close relation with an ON-resistance value. For instance, if the impurity concentration of the p-type drift region 110 is low, breakdown can occur at the edge of a drain and if the impurity concentration of the p-type drift region 110 is high, breakdown can occur at an edge of a gate. Therefore, the impurity concentration profile at the high voltage semiconductor device must be maintained as initially set. However, during the formation of the high voltage semiconductor device, redistribution of the impurities can occur due to an annealing process performed at a high temperature for the long period of time.

Referring to FIG. 1B, a thermal oxide layer 120 is formed on the semiconductor substrate 100. The thermal oxide layer 120 can be formed by annealing the semiconductor substrate 100.

For instance, the semiconductor substrate 100 is exposed to an oxidation atmosphere after being placed in a furnace. During a linear stage, oxygen atoms bond with silicon atoms of the semiconductor substrate to form the thermal oxide layer 120. When a thermal oxide layer is grown to a thickness of 500 angstroms, it is difficult for oxygen atoms to be in direct contact with the semiconductor substrate 100. However, unreacted oxygen atoms penetrate the thermal oxide layer. As a result, the thermal oxide layer continuously grows. However, a growth rate of the thermal oxide layer is low.

The thermal oxide layer 120 grows above the surface of the semiconductor substrate 100 while growing to the inside of the semiconductor substrate 100. As a result, when the thermal oxide layer is completely formed, the surface of the semiconductor substrate 100 is recessed. In other words, the single crystalline silicon layer 105 has a second thickness “B” that is smaller than the first thickness “A”. At this time, the impurity concentration profile previously set at the single crystalline silicon layer 105 can change. In this regard, time and temperature are controlled to prevent a change of the initially defined impurity concentration profile and, thus, a thermal oxide layer is formed to be thinner than a general thermal oxide layer.

For instance, it is preferable that a thickness of the thermal oxide layer is 3000 angstroms or less. The impurity concentration profile is formed in a specific form from the surface of the semiconductor substrate to a predetermined depth. If a thin thermal oxide layer is formed on the surface of the semiconductor substrate, the impurity concentration profile may not be affected by the thermal oxide layer because a depth of the p-type drift region is considerably large relative to the thin thermal oxide layer. Since the formation of the thin thermal oxide layer can be conducted at a relatively low temperature for a short period of time, there can be no change in the impurity concentration profile. Therefore, the change of the impurity concentration profile can be negligible compared with an original profile of an impurity region in a conventional device.

The impurity region and the thermal oxide layer can be formed by different process steps.

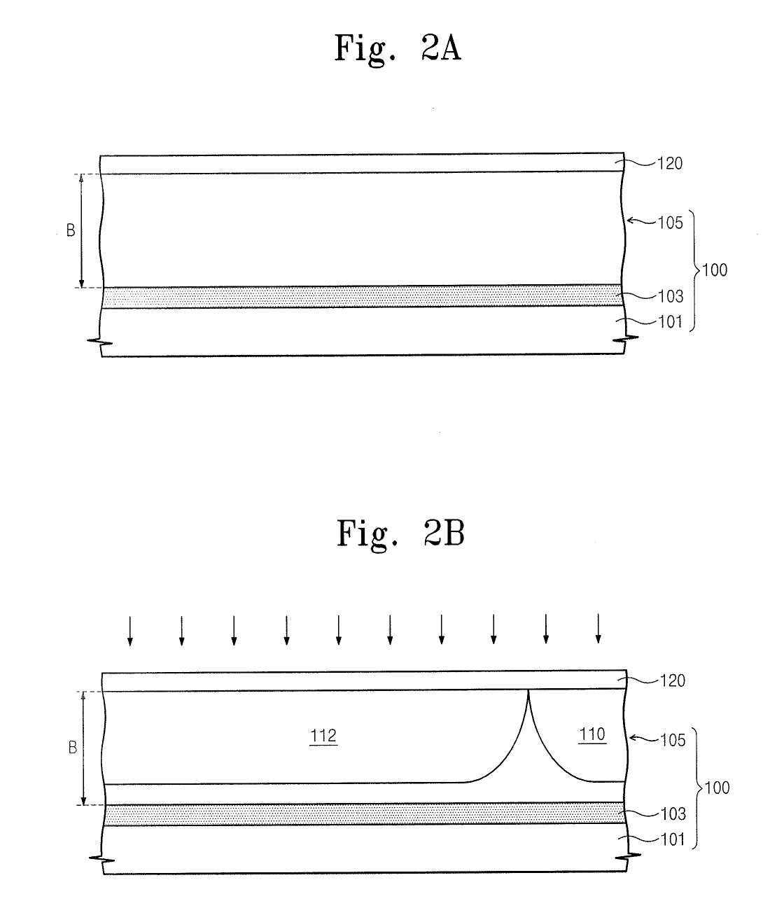

Referring to FIG. 2A, a semiconductor substrate 100 is provided. The semiconductor substrate 100 includes a lower silicon substrate 101, a buried insulating layer 103 formed on the lower silicon substrate 101, and a single crystalline silicon layer 105 having a first thickness (not shown) formed on the buried insulating layer 103.

A thermal oxide layer 120 is formed on the semiconductor substrate 100. The thermal oxide layer 120 can be formed by annealing the semiconductor substrate 100. The thermal oxide layer 120 grows upwardly while growing to the inside of the semiconductor substrate 100 from a surface of the semiconductor substrate 100. As a result, when the thermal oxide layer 120 is completely formed, the surface of the semiconductor substrate 100 is recessed to make the single crystalline silicon layer 105 have a second thickness “B”. However, since an impurity region is not defined at the semiconductor substrate, the thermal oxide layer 120 does not affect the impurity concentration profile. For instance, if a thickness of the thermal oxide layer exceeds 3000 angstroms, it is difficult to control the energy of an ion implantation process (IIP). Thus, the thickness of the thermal oxide layer is approximately 3000 angstrom or less in the present embodiment.

Referring to FIG. 2B, impurities are implanted into the semiconductor substrate 100 to define impurity regions. The implantation of the impurities can be performed by the ion implantation process (IIP). Since the thermal oxide layer 120 is formed on the semiconductor substrate 100, ions are introduced into the semiconductor substrate 100 at a relatively higher energy than when the thermal oxide layer 120 is not formed.

A p-type drift region 110 and an n-type well region 112 can be formed at the single crystalline silicon layer by the impurity implantation to have a predetermined depth from the surface of semiconductor substrate. The p-type drift region 110 and the n-type well region 112 can have impurity concentration profiles that exhibit a specific form relative to the surface of the semiconductor substrate, respectively.

Processes described below will be performed for the results structure illustrated in FIG. 1B or FIG. 2B. That is, the processes represent embodiments of methods that can be used to form the structures of FIG. 1B and FIG. 2B.

Referring to FIG. 1C, a hard mask layer (not shown) is formed on the thermal oxide layer 120. The hard mask layer can be a single layer or a multiple layer. For instance, the hard mask layer can be a multiple layer of silicon nitride SiN and oxide. The oxide can be a plasma enhanced chemical vapor deposition (PECVD) oxide.

A first photoresist layer (not shown) is formed on the hard mask layer. The first photoresist layer is patterned by an exposure process and a development process to form a first photoresist pattern 125. The hard mask layer is etched using the first photoresist pattern 125 to form a hard mask pattern 123.

A portion of the thermal oxide layer 120 is etched using the hard mask pattern 123 to expose the surface of the single crystalline layer 105. The first photoresist pattern 125 can be removed by a conventional ashing process.

Referring to FIG. 1D, a portion of the single crystalline layer 105 is etched using the hard mask pattern 123 to expose the buried insulating layer 103. As a result, a deep trench 130 is formed.

Thereafter, the hard mask pattern 123 is removed. In the case where the hard mask pattern 123 includes oxide, a portion of the thermal oxide layer around the deep trench 130 can be etched.

Referring to FIG. 1E, a chemical vapor deposition CVD oxide layer 135 is formed on the thermal oxide layer 120 including the deep trench 130. The CVD oxide layer 135 is uniformly formed on the bottom surface and the sidewall of the deep trench 130. The CVD oxide layer 135 is formed by reacting source gases at the surface of the semiconductor substrate 100. Unlike the conventional thermal oxide layer 120, the CVD oxide layer 135 is formed only at the outside of the semiconductor substrate 100. Therefore, the CVD oxide layer 135 does not affect the impurity concentration profile formed at the semiconductor substrate 100. That is, an insulating layer having a sufficient thickness can be formed using the CVD oxide layer 135. For instance, the entire thickness of the CVD oxide layer 135 and the thermal oxide layer 120 can be at least several thousands angstrom.

An insulating layer is formed on the CVD oxide layer 135. The insulating layer can be a polysilicon layer 140 with an excellent gap-fill characteristic.

Referring to FIG. 1F, the polysilicon layer 140 is planarized to form a polysilicon pattern 145 filling the deep trench 130. The planarization can be performed by an etchback process or a chemical mechanical polishing CMP process, as examples.

Within the deep trench, a central portion of the polysilicon pattern 145 can be recessed. When the polysilicon layer 140 is formed, the central portion of the polysilicon layer 140 in the deep trench 130 can be lower than adjacent portions due to a step difference caused by the deep trench. Thus, even if the polysilicon layer 140 is planarized in a subsequent process, the central portion of the polysilicon pattern 145 can be lower than an adjacent CVD oxide layer 135. To overcome the foregoing, a capping oxide layer 146 is further formed on the polysilicon pattern. Though the capping oxide layer 146 can be formed by means of an annealing process, it does not affect the concentration profile of the impurity region because the thermal oxide layer 120 and the CVD oxide layer 135 are considerably thick.

A second photoresist layer (not shown) is formed on the polysilicon pattern 145 and the CVD oxide layer 135. The second photoresist layer is patterned by means of a conventional photolithography process to form a second photoresist pattern 150.

Referring to FIG. 1G, the CVD oxide layer 135 and the thermal oxide layer 120 are etched using the second photoresist pattern 150 to expose the semiconductor substrate 100. As a result, a gate insulating layer 160 and a device isolation pattern 170 are formed simultaneously. Therefore, the gate insulating layer 160 and the device isolation pattern 170 can be formed using the one photoresist pattern 150.

The thermal oxide layer 120 is denser than the CVD oxide layer 135. Since the thermal oxide layer 120 and the CVD oxide layer 135 are different in material characteristics, they have different etching selectivities under the same etching process. Thus, if the thermal oxide layer 120 and the CVD oxide layer 135 are etched using the same process, the sidewall of the gate insulating layer 160 and the device isolation pattern 170 can be inclined.

Referring to FIG. 1H, the second photoresist pattern 150 is removed. A gate electrode 180 can be formed on the gate insulating layer 160. The gate electrode 180 can be formed on the gate insulating layer 160 and the semiconductor substrate 100. In this case, a gate oxide layer 165 is interposed between the semiconductor substrate 100 and the gate electrode 180.

An embodiment of a high voltage semiconductor device according to an aspect of the present invention will now be described below in detail with reference to FIG. 1H.

A semiconductor substrate 100 can be a silicon-on-insulator SOI substrate including a buried insulating layer 103 and a single crystalline silicon layer 105. The semiconductor substrate 100 includes the buried insulating layer 103 and the single crystalline silicon layer 105, which are sequentially stacked on a lower silicon substrate 101. A p-type drift region 110 and an n-type well region 112 are defined at the semiconductor substrate 100.

A gate insulating layer 160 is provided on the semiconductor substrate 100 to have a bottom surface being even with the flat top surface of the semiconductor substrate 100, and to have a thickness of at least several thousands of angstroms. The bottom surface of the gate insulating layer 160 is in contact with the top surface of the semiconductor substrate 100. The gate insulating layer 160 includes a thermal oxide layer 120a and a CVD oxide layer 135a, which are stacked and collectively have an inclined sidewall. For instance, a section of the gate insulating layer 160 can be an isosceles trapezoidal. Thus, the top surface of the gate insulating layer 160 can extend in parallel with the top surface of the semiconductor substrate 100.

A device isolation layer 170 can be provided on the semiconductor substrate 100 to be spaced apart from the gate insulating layer 160. The device isolation layer 170 includes a penetrative portion penetrating the single crystalline silicon layer 105 from the surface of the semiconductor substrate 100 to the buried insulating layer 103 and a protrusive portion protruding above the top surface of the semiconductor substrate 100. The outside of the penetrative portion can be a CVD oxide pattern, and the inside of thereof can be a polysilicon pattern 145. The center of the protrusive portion includes the polysilicon pattern 145, and the thermal oxide pattern 120a and the CVD oxide layer 135a are stacked around the polysilicon pattern 145. Like the gate insulating layer 160, a sidewall of the protrusive portion is inclined. A height of the protrusive portion can be equal to a thickness of the gate insulating layer 160.

In the case where the central portion of the polysilicon pattern 145 is recessed, a gap-fill insulating layer 146 can be further provided on the top surface of the polysilicon pattern 145.

A gate electrode 180 is provided on the gate insulating layer 160 and the semiconductor substrate 100. Thus, the gate electrode 180 has a step difference along the profile of the top surface of the gate insulating layer 160 and the semiconductor substrate 100. A gate oxide layer 165 can be further provided between the gate electrode 180 and the semiconductor substrate 100.

What is claimed is:

1. A method of forming a high voltage semiconductor device, comprising:
thermally oxidizing a semiconductor substrate to form a thermal oxide layer;
uniformly forming a chemical vapor deposition (CVD) oxide layer on the thermal oxide layer;
forming a gate mask pattern on the CVD oxide layer;
etching the CVD oxide layer and the thermal oxide layer using the gate mask pattern at a different etch rate to expose a portion of the semiconductor substrate, thereby forming a gate insulating layer having an inclined sidewall; and
forming a gate electrode on the gate insulating layer.

2. The method of claim 1, wherein the semiconductor substrate is a silicon-on-insulator (SOI) substrate including a buried insulating layer and a semiconductor layer.

3. The method of claim 2, before forming the CVD oxide layer, further comprising:
forming a trench by etching a portion of the thermal oxide layer and the semiconductor layer.

4. The method of claim 3, wherein the forming the trench comprises:
forming a mask insulating layer on the thermal oxide layer;
forming a photoresist pattern on the mask insulating layer;
etching the mask insulating layer and the thermal oxide layer using the photoresist pattern to form a trench mask pattern; and
etching the semiconductor layer using the trench mask pattern to expose the buried insulating layer.

5. The method of claim 4, including forming the CVD oxide layer on a bottom surface and a sidewall of the trench, and on the thermal oxide layer.

6. The method of claim 5, further comprising:
filling the trench, in which the CVD oxide layer is formed, with an insulating material.

7. The method of claim 6, wherein the insulating material is polysilicon.

8. The method of claim 7, wherein filling the trench comprises:
forming a polysilicon layer on the semiconductor substrate to fill the trench; and
planarizing the polysilicon layer down to a top surface of the CVD oxide layer to form a polysilicon pattern.

9. The method of claim 8, wherein the gate mask pattern covers the polysilicon pattern, and forming the gate insulating layer is simultaneously performed with forming a device isolation pattern including the polysilicon pattern.

10. The method of claim 9, wherein the gate electrode is formed on a top surface of the gate insulating layer and the semiconductor substrate.

11. The method of claim 10, further comprising:
forming a capping oxide layer to cover a top surface of the polysilicon pattern.

12. The method of claim 1, including defining an impurity region at the semiconductor substrate.

13. A high voltage semiconductor device, comprising:
a semiconductor substrate including a buried insulating layer and a semiconductor layer;
a gate insulating layer having a bottom surface that is even with a flat top surface of the semiconductor substrate and including a thermal oxide layer pattern and a CVD oxide layer pattern that are stacked sequentially, wherein a sidewall of the gate insulating layer is inclined; and
a gate electrode formed on the gate insulating layer.

14. The high voltage semiconductor device of claim 13, further comprising:
a device isolation pattern spaced apart from the gate insulating layer and penetrating the semiconductor layer from the surface of the semiconductor substrate to expose the buried insulating layer, the device isolation pattern including a CVD oxide layer pattern and a polysilicon pattern.

15. The high voltage semiconductor device of claim 14, wherein the device isolation pattern includes a protrusive portion protruding above the top surface of the semiconductor substrate, and a sidewall of the protrusive portion is inclined.

16. The high voltage semiconductor device of claim 13, wherein a section of the gate insulating layer is formed in an isosceles trapezoid shape.

17. The high voltage semiconductor device of claim 13, wherein the gate electrode has a step difference along a profile of a top surface of the gate insulating layer and the semiconductor substrate.

18. The high voltage semiconductor device of claim 13, further comprising:
a capping oxide layer formed on a top surface of the device isolation pattern.
